(19) United States
(12) Patent Application Publication
(10) Pub. No.: US 2019/0059160 A1
(43) Pub. Date: Feb. 21, 2019

(54) Electronic Device and Method of Making the Same Using Surface Mount Technology

(71) Applicant: Thin Film Electronics ASA, Oslo (SE)

(72) Inventor: Olle HAGEL, Linköping (SE)

(73) Assignee: Thin Film Electronics ASA, Oslo (NO)

(21) Appl. No.: 16/078,887

(22) PCT Filed: Feb. 27, 2017
(86) PCT No.: PCT/IB2017/051112

§ 371 Date: Aug. 22, 2018

Related U.S. Application Data
(60) Provisional application No. 62/301,243, filed on Feb. 29, 2016.

(51) Int. Cl. H05K 3/32; C09J 9/02; C09J 5/06; H05K 3/30; H01L 23/00; H05K 1/03; H05K 1/18

(52) U.S. Cl. CPC H05K 3/323; H05K 2203/168; C09J 5/06; H05K 3/303; H01L 24/75; H05K 1/0393; H05K 1/189; H01L 2224/83874; H01L 2224/83851; H01L 2224/83132; H01L 2224/75753; H01L 2224/75842; H01L 2224/759; H01L 2224/75611; H01L 2224/75651; H05K 2201/10098; H05K 2201/10151; H05K 2201/10128; C09J 9/02

(57) ABSTRACT

A method of and system for manufacturing an electronic device, a curable conductive adhesive for use in the same, and an electronic device are disclosed. The method includes printing a conductive adhesive onto pads at ends of traces on a substrate, placing one or more components having a non-standard size and/or shape onto the pads with the conductive adhesive thereon, and after the component(s) have been placed onto the pads, curing the conductive adhesive at a predetermined temperature or with light having a predetermined wavelength (band). The system comprises a printer configured to print a conductive adhesive onto pads at ends of traces on a substrate, a surface mounting machine configured to place one or more components having a non-standard size and/or shape onto the pads with the conductive adhesive thereon, and a curing station configured to cure the conductive adhesive after the component(s) have been placed onto the pads.

### CROSS REFERENCE TO RELATED APPLICATION

This application claims the benefit of U.S. Provisional Pat. Appl. No. 62/301,243, filed on Feb. 29, 2016, incorporated herein by reference as if fully set forth herein.

### FIELD OF THE INVENTION

The present invention generally relates to integration and assembly of electronic devices. More specifically, embodiments of the present invention pertain to an electronic device and a method of making the same using surface mount technology, as well as an anisotropic conductive paste (ACP) useful in the method.

### DISCUSSION OF THE BACKGROUND

Components to be placed and mounted onto a circuit board often have a non-standard size and/or shape. Some components may also be temperature-sensitive and/or flexible. Non-standard sizes and shapes, temperature sensitivity and flexibility can result in challenges when placing and mounting components onto a circuit board using equipment designed for assembling standardized components.

However, processing using standardized surface mount technology (SMT) assumes that the components are rigid, have standard shapes, and are compatible with conventional soldering temperatures. For example, in pulsed heated soldering, the thermodes that apply the heat must be perfectly parallel to the component, and therefore may not be useful for soldering a flexible component.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

The present invention relates to electronic devices, methods of manufacturing the same, and an anisotropic conductive paste (ACP) useful in the methods.

In one aspect, the present invention relates to a method of manufacturing an electronic device, comprising printing a conductive adhesive onto pads at ends of traces on a substrate, placing one or more components having a non-standard size and/or shape onto the pads with the conductive adhesive thereon, and after the component(s) have been placed onto the pads of the substrate, curing the conductive adhesive at a predetermined temperature or with light having a predetermined wavelength or wavelength band.

In various embodiments of the present invention, the conductive adhesive is cured at the predetermined temperature, which may be in the range of about 50° C. to 140° C. The conductive adhesive may be an anisotropic conductive paste (ACP). The ACP may include one or more polymerizable monomers, one or more co-monomers and one or more conductive filaments or particles dispersed in the ACP. The co-monomer(s) may be co-polymerized with the polymerizable monomers. In addition, the co-monomer(s) may have a formula with at least three functional groups that are co-polymerizable with the polymerizable monomer(s). In some embodiments of the present invention, the ACP may further include a thermally activated initiator.

In some embodiments of the present invention, the conductive adhesive may be cured upon irradiation with light having a wavelength within a predetermined band. For example, the light may be or comprise ultraviolet light. In addition, a non-conductive adhesive may be dispensed onto one or more predetermined locations of the substrate other than the pads. One or more components may be placed on the predetermined location(s).

In various embodiments of the present invention, the substrate may include a printed circuit board (PCB). In other embodiments, the substrate may be flexible. For example, the substrate may comprise a plastic sheet or film, paper, a metal foil or film, or a combination thereof. Alternatively, the substrate may include a flexible material secured to a rigid substrate, in which the flexible material comprises a plastic sheet or film, paper, a metal foil or film, or a combination thereof.

In further embodiments of the present invention, one or more additional components having a standard size and/or shape may be placed onto a subset of the pads. Alternatively or in addition, one or more additional components may be placed onto the pads using a standard and/or uncustomized surface mount technology (SMT) machine.

Generally, the SMT machine may include a substrate holder or clamp, a gantry, and a tape-and-reel station. In some embodiments of the present invention, the gantry may include pick-and-place machinery, in which the gantry may be configured to pick up, optionally inspect, and place the components on predetermined locations on the substrate. The gantry may include a plurality of nozzles attached to a plotter or plotter-like device that can manipulate the nozzles in three dimensions. Each nozzle may be independently rotatable. At least one of the nozzles may have a surface with a shape identical to or configured to match a shape of the component it picks up. Alternatively or in addition, at least one of the nozzles may have a surface that extends below an uppermost surface of the component. The gantry may also include a plurality of robotic heads configured to work independently of each other.

In some embodiments of the present invention, the SMT machine may include a camera or other inspection equipment. The camera or other inspection equipment may include a camera configured to conduct automated optical inspection (AOI). Alternatively or in addition, the SMT machine may include a conveyor belt, along which the substrate travels. The SMT machine may further include a plurality of conveyors that may be configured to simultaneously produce a plurality of the same or different products.

Furthermore, the method may include inspecting a rotational position of the component(s). In some embodiments of the present invention, placement of the component(s) onto the substrate may be inspected. After curing the conductive adhesive, the substrate may be cleaned. Alternatively or in addition, one or more of the components may be cleaned. The method may further include testing the electronic device. In another aspect, the present invention relates to a system for manufacturing an electronic device, comprising a printer configured to print a conductive adhesive onto pads at ends of traces on a substrate, a surface mounting machine configured to place one or more components having a non-standard size and/or shape onto the pads with the conductive adhesive thereon, and a curing station, configured to cure the conductive adhesive after the component(s) have been placed onto the pads of the substrate. In addition, the system may include a feeder configured to feed the substrate into the printer, and/or a collector configured to receive the substrate from the curing station. The SMT machine may be a standard and/or uncustomized SMT machine. For example, the SMT machine may include a substrate holder or clamp, a gantry, and a tape-and-reel station. Furthermore, the gantry may include pick-and-place machinery, in which the gantry is configured to pick up, optionally inspect, and place the components on predetermined locations on the substrate. The gantry may include a plurality of nozzles attached to a plotter or plotter-like device that can manipulate the nozzles in three dimensions. Each nozzle may be independently rotatable. At least one of the nozzles may have a surface with a shape identical to or configured to match a shape of the component it picks up. Alternatively or in addition, at least one of the nozzles may have a surface that extends below an uppermost surface of the component. Furthermore, the gantry may include a plurality of robotic heads configured to work independently of each other.

The SMT machine may further include a camera or other inspection equipment. The camera or other inspection equipment may comprise a camera configured to conduct automated optical inspection (AOI). Also, the SMT machine may include a conveyor belt, along which the substrate travels. The SMT machine may further include a plurality of conveyors and be configured to simultaneously produce a plurality of the same or different products.

In various embodiments of the present invention, the printer may include a screen or stencil printer. The printer may be configured to print the traces and the pads on the substrate. In addition, the printer may include a glue-dispensing machine configured to apply a non-conductive adhesive to the substrate.

In further embodiments, the curing station may include an oven or heater. The oven or heater is configured to heat the substrate, the conductive adhesive and the one or more components to a temperature sufficiently high to cure the conductive adhesive. The temperature maybe, for example about 50° C. to 140° C. Alternatively or additionally, the curing station may include a source of UV radiation.

In yet another aspect, the present invention relates to an electronic device, comprising a substrate having a plurality of traces thereon, each of the traces having a pad at one or more ends thereof, one or more components having a non-standard size and/or shape, and a cured conductive adhesive between the pads and the one or more components. Each of the one or more components is on a first subset of the pads. The cured conductive adhesive electrically connects one of the pads to a corresponding terminal of the one or more components.

In addition, the device may include one or more additional components having a standard size and/or shape on a second subset of the pads. Typically, one or more of the components are selected from the group consisting of a sensor, an antenna, and a display. Furthermore, one or more layers of the sensor, the antenna, and/or the display may include a printed material. A plurality of layers of the sensor, the antenna, and/or the display may include a printed layer. Generally, one or more of the additional components are selected from the group consisting of an integrated circuit and a battery. One or more layers of the integrated circuit and/or the battery may include a printed material. Furthermore, a plurality of layers of the integrated circuit and/or the battery may include a printed layer.

In various embodiments of the present invention, the substrate may include a printed circuit board (PCB). Alternatively, the substrate may be flexible. For example, the substrate may include a plastic sheet or film, paper, a metal foil or film, or a combination thereof. In a further alternative, the substrate may include a flexible material secured to a rigid substrate, in which the flexible material includes a plastic sheet or film, paper, a metal foil or film, or a combination thereof.

Generally, the conductive adhesive may be an anisotropic conductive paste (ACP). The ACP may include one or more polymerizable monomers, one or more co-monomers, and one or more conductive filaments or particles dispersed in the ACP. The co-monomer(s) may be co-polymerized with the polymerizable monomers. In addition, the co-monomers may have a formula with at least three functional groups that are co-polymerizable with the one or more polymerizable monomers. The ACP may further include a thermally activated initiator. Alternatively, the ACP may include a radiation-activated initiator. The radiation may be or comprise ultraviolet light.

In other embodiments of the present invention, the device may include a non-conductive adhesive on one or more predetermined locations of the substrate other than the pads. The component(s) may be on the one or more predetermined locations.

Yet another aspect of the invention relates to an anisotropic conductive paste (ACP; the curable conductive adhesive), comprising an initiator that is thermally activated or activated upon irradiation with light having a wavelength within a predetermined band, one or more monomers that are polymerized by the activated initiator, one or more co-monomers that are co-polymerized with the monomers, and elastic conductive filaments or particles dispersed in the conductive adhesive. The co-monomer(s) have a formula with at least three functional groups that are co-polymerizable with the monomer(s) by the activated initiator. The conductive adhesive is curable at a temperature of 150° C. or less. For example, the conductive adhesive may be curable at a temperature of 80-140° C.

In various embodiments of the present invention, the elastic conductive filaments or particles may include elastic particles coated with an elemental, conductive metal or alloy. The elastic particles may include a polymer having a Young's modulus of about 3.5 GPa or less. For example, the Young's modulus may be 2 GPa or less. The elastic particles may include polyethylene, polypropylene, polystyrene, a rubber, poly(ethylene-vinyl acetate), a blend or copolymer thereof, or a silicone polymer. The elastic particles may be coated with silver, gold, copper, nickel, or aluminum.

The initiator may be present in an amount of from 0.1 to 10 wt %. The monomer(s) may be present in an amount of from 10 to 70 wt %. The one or more co-monomers may be present in an amount of from 0.1 to 10 wt %. The conductive filaments or particles may be present in an amount of from 1 to 20 wt %.

The conductive adhesive may further include a solvent. The solvent may be present in an amount of from 10 to 70 wt %. The solvent may be selected from the group consisting of alkanes, cycloalkanes, alkanes substituted with one or more halogen atoms, cycloalkanes substituted with one or more halogen atoms, arenes, arenes substituted with one or more alkyl, alkoxy and/or halogen atoms, ethers, cyclic ethers, esters, glycols, glycol ethers, glycol esters, and siloxanes. For example, the solvent may be a C₆-C₁₀ alkane, a C₆-C₁₀ cycloalkane, a C₆-C₁₀ arene, a C₆-C₁₀ arene substituted with 1 to 3 C₁-C₄ alkyl groups, a C₁-C₄ alkoxy group or 1 to n halogen atoms (where n is the number of carbon atoms in the arene), a C₄-C₁₀ dialkyl ether, a C₄-C₁₀ cyclic ether, a C₇-C₁₆ alkyl aryl ether, a C₁₂-C₁₆ diaryl ether, a C₁₃-C₁₆ aryl aralkyl ether, a C₁₄-C₁₆ diaralkyl ether, a C₁-C₄ alkyl ester of a C₁-C₆ alkanoic or C₇-C₁₀ aralkanoic acid, a C₂-C₆ alkylene glycol, a C₁-C₄ mono- or dialkyl ether of a C₂-C₆ alkylene glycol, and a C₁-C₆ alkanoic ester of a C₁-C₄ monoalkyl ether of a C₂-C₆ alkylene glycol.

In various embodiments, the monomer(s) may be selected from the group consisting of alkenes, cycloalkenes, and aryl alkenes, any of which may be substituted with one or more halogen and/or alkoxy groups; acrylates and methacrylates; epoxides; epoxides substituted with from one or more halogen atoms, alkoxy groups or alkoxy-substituted alkyleneoxy groups; and glycidyl ethers and esters. For example, the monomer(s) may be a C₆-C₁₀ alkene, a C₆-C₁₀ cycloalkene, a C₅-C₁₀ aryl alkene, a C₆-C₁₀ alkene substituted with one or more halogen and/or C₁-C₄ alkoxy groups, a C₆-C₁₀ cycloalkene substituted with one or more halogen and/or C₁-C₄ alkoxy groups, a C₅-C₁₀ aryl alkene substituted with one or more halogen and/or C₁-C₄ alkoxy groups, a C₁-C₄ ester of acrylic or methacrylic acid, ethylene oxide substituted with 1 to 4 C₁-C₁₀ alkyl, aryl and/or aralkyl groups, or ethylene oxide substituted with 1 or 2 C₁-C₄ alkyl groups, one of which is further substituted with a C₁-C₄ alkoxy group or a C₁-C₄ alkoxy-substituted C₂-C₄ alkyleneoxy group.

In further embodiments, the co-monomer(s) may be selected from the group consisting of esters of di- and triacrylates and methacrylates. For example, the co-monomer(s) may be selected from the group consisting of C₁-C₄ esters of C₄-C₁₂ di- and triacrylates and methacrylates, and in particular, from the group consisting of C₁-C₄ esters of C₇-C₁₂ triacrylates and C₁₀-C₁₂ trimethacrylates. The co-monomer(s) may provide a predetermined amount or level of shrinkage after curing.

The conductive filaments or particles may include a particle, powder, flake or needle of an elemental, conductive metal or a conductive alloy. The elemental, conductive metal may include silver, copper, nickel, or titanium. The conductive alloy may include silver, copper, steel, nickel, or titanium.

The present invention advantageously avoids the high cost of full-system assembly (pick and place) associated with high-end SMT machines. The present method can be implemented using basic and/or standard, low-cost machines widely available using standard SMT services and/or processing. The present invention also avoids the relatively high temperatures associated with solder and solder reflux processes, and addresses shortcomings of nozzles with standard shapes and SMT equipment that is incompatible with flexible components. These and other advantages of the present invention will become readily apparent from the detailed description of various embodiments below.

### BRIEF DESCRIPTION OF THE DRAWINGS

FIG. 1 is a flow chart for an exemplary method of placing components on a substrate according to embodiments of the present invention.

FIG. 2 is a block diagram of an exemplary system for placing components on a substrate according to embodiments of the present invention.

FIGS. 3A-B are block diagrams of exemplary smart tags or smart labels according to embodiments of the present invention.

FIG. 4 is a block diagram of an exemplary integrated circuit is useful in the smart tags or smart labels according to one or more embodiments of the present invention.

FIGS. 5A-D are views of an exemplary nozzle useful in the SMT machine of FIG. 2 according to one or more embodiments of the present invention.

FIGS. 6A-D are views of another exemplary nozzle useful in the SMT machine of FIG. 2 according to one or more embodiments of the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures and components have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

For the sake of convenience and simplicity, the terms “conductive adhesive,” “anisotropic conductive paste,” “asymmetric conductive paste,” and “ACP” are, in general, interchangeable and may be used interchangeably herein, but are generally given their art-recognized meanings. Wherever one such term is used, it also encompasses the other terms. In addition, for convenience and simplicity, the terms “part,” “portion,” and “region” may be used interchangeably but these terms are also generally given their art-recognized meanings. Also, unless indicated otherwise from the context of its use herein, the terms “known,” “fixed,” “given,” “certain” and “predetermined” generally refer to a value, quantity, parameter, constraint, condition, state, process, procedure, method, practice, or combination thereof that is, in theory, variable, but is typically set in advance and not varied thereafter when in use.

The present invention advantageously enables manufacturing of electrical devices using flexible components and/or components having a non-standard size. Furthermore, the present invention allows conventional and/or standardized SMT machines to be used instead of expensive, high-end machines, thereby reducing the cost and/or processing time for manufacturing certain electrical devices. In addition, the present invention advantageously reduces the manufacturing time since conventional or standard SMT machines (which are ubiquitous and widely available at many companies) can be used. Even further, the present process can advantageously use an ACP that can be cured at a temperature of 140° C. or less, a temperature at which heat-sensitive components and/or layers can be protected. Also, the present system and process can avoid use of expensive thermodes by selecting an ACP binder that contracts or shrinks upon heating and/or activation.

An Exemplary Method of Making an Electronic Device

The present invention concerns a method of manufacturing an electronic device, comprising printing a conductive adhesive onto pads at the ends of traces on a substrate, placing one or more components having a non-standard size and/or shape onto the pads with the conductive adhesive thereon, and after the component(s) have been placed onto the pads of the substrate, curing the conductive adhesive at a predetermined temperature or with light having a predetermined wavelength or wavelength band. In various embodiments, the predetermined temperature is 140° C. or less, and multiple components are placed onto the substrate using a conventional SMT machine that may have one or more nozzles that have been modified for the non-standard size and/or shape of one or more of the multiple components.

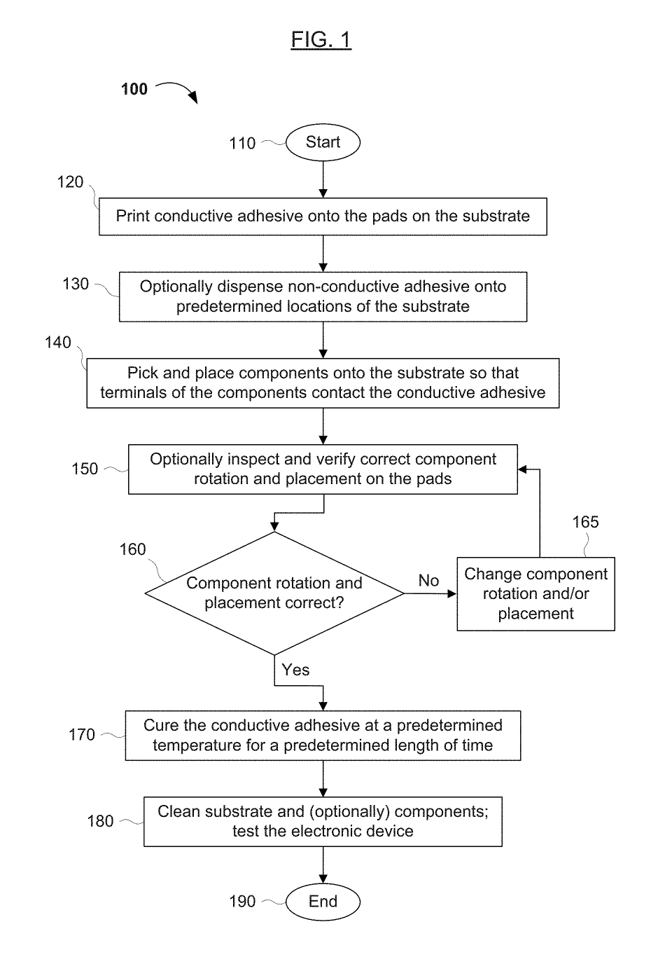

FIG. 1 shows a flow chart 100 outlining an exemplary method of manufacturing an electronic device. At 110, the method starts, and at 120, a conductive adhesive is applied to the pads at the ends of traces on the substrate, for example using a screen printer. Alternatively, the conductive adhesive may be applied to the pads by stenciling or syringe dispensing. The substrate may be, for example, a printed circuit board (PCB) or other substrate that can be processed in conventional SMT equipment. In some preferred embodiments, the substrate has a planar or substantially planar uppermost surface, and the traces are printed (e.g., screen-printed) thereon using a conductive paste.

In various embodiments, the conductive adhesive is an ACP. In some such embodiments, the ACP can be custom-designed for a specific (e.g., low) curing temperature, such as 140° C. or less (e.g., 80-140° C.). In general, the ACP comprises (i) a conductor, (ii) a binder (e.g., a curable polymer), and (iii) a solvent. The conductor may be a particle, powder, flake or needle of an elemental, conductive metal or alloy (e.g., silver, copper, steel, nickel, titanium, etc.), or a particle coated with an elemental, conductive metal or alloy, particularly a relatively elastic particle. For example, particles such as silica, alumina, an elastic polymer having a relatively low Young's modulus (e.g., of about 3.5 GPa, 2 GPa, or less) such as polyethylene, polypropylene, polystyrene, a rubber (e.g., polybutadiene, polyisoprene, a polyacrylate, a copolymer thereof with one or more alkenes or alkadienes, a blend thereof with one or more polyalkenes or poly[alkene-alkadiene] copolymers, etc.), poly(ethylene-vinyl acetate), a blend or copolymer thereof, a silicone polymer, etc., coated with an elemental metal such as silver, gold, copper, nickel, aluminum, etc. may be suitable for use in the present ACP. The conductive particles may be present in the ACP in an amount of from 1 to 20 wt %. The binder may be present in an amount of from 10 to 80 wt %, and the solvent may be present in an amount of from 10 to 70 wt %. The ACP may further comprise a curing agent (e.g., a conventional thermal or radiation-induced curing agent), in an amount of from 0.1 to 10 wt %.

The binder may be a monomer that is polymerizable by thermal or radiation (e.g., UV light) curing. For example, the monomer may be selected from the group consisting of alkenes (e.g., C₆-C₁₀ alkenes, cycloalkenes and aryl alkenes, which may be substituted with one or more halogen and/or C₁-C₄ alkoxy groups), acrylates and methacrylates (e.g., C₁-C₄ esters of acrylic and/or methacrylic acid), epoxides (e.g., ethylene oxide substituted with 1 to 4 C₁-C₁₀ alkyl, aryl and/or aralkyl groups, which may be further substituted with from one or more halogen atoms and/or C₁-C₄ alkoxy groups or C₁-C₄ alkoxy-substituted C₂-C₄ alkyleneoxy groups, glycidyl ethers and esters, etc.), The ACP may also be custom-designed for a particular amount or level of shrinkage, for example by specifying certain binder components (e.g., C₁-C₄ esters of C₄-C₁₂ di- and/or tri[meth]acrylates, which may be present in an amount of from 0.1 to 10 wt %).

The solvent may be selected from one or more alkanes (e.g., C₆-C₁₀ alkanes and cycloalkanes, which may be substituted with one or more halogen atoms), arenes (e.g., C₆-C₁₀ arenes that may be substituted with one or more C₁-C₄ alkyl or alkoxy groups and/or halogen atoms), ethers (e.g., C₄-C₁₀ dialkyl or cyclic ethers, C₇-C₁₆ alkyl aryl, diaryl, aryl aralkyl or diaralkyl ethers, etc.), esters (e.g., C₁-C₄ alkyl esters of C₁-C₆ alkanoic or C₇-C₁₀ aralkanoic acids), glycols (e.g., C₂-C₆ alkylene glycols), glycol ethers (e.g., C₁-C₄ mono- or dialkyl ethers of C₂-C₆ alkylene glycols, such as glyme, diglyme, etc.), glycol esters (e.g., C₁-C₆ alkanoic esters of C₁-C₄ monoalkyl ethers of C₂-C₆ alkylene glycols), siloxanes, etc.

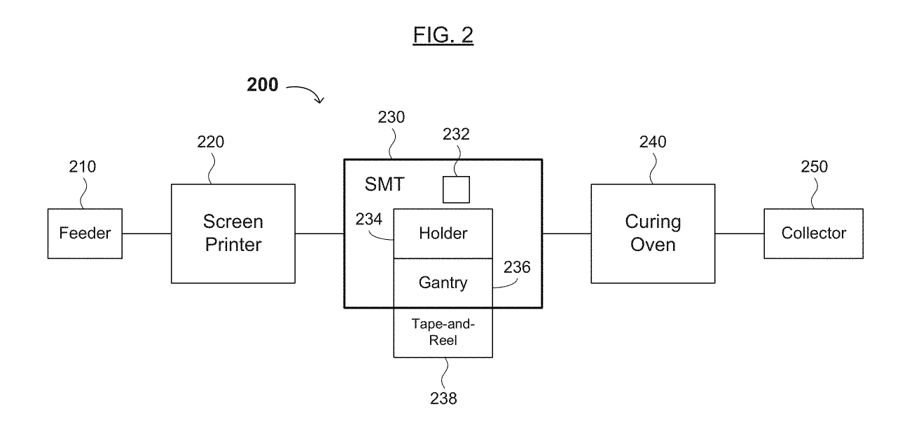

At 130, a non-conductive adhesive may optionally be dispensed onto the substrate in one or more predetermined locations. The non-conductive adhesive is not necessary when the components are adhered to the tape in the tape-and-reel station (e.g., 238 in FIG. 2) using a display tape, which can be transferred with the component to the substrate to keep the component from moving. However, when such a display tape is not present, then a non-conductive adhesive can be applied (e.g., by screen printing) to one or more locations within the pads on the substrate to hold the component in place prior to curing the conductive adhesive.

At 140, the component(s) are picked up and placed on the substrate in predetermined locations, such that the electrical terminals of the component(s) contact the pads on which the ACP has been printed. For example, a conventional pick-and-place machine may pick up, inspect, and place one or more components having an irregular or non-standard size and/or shape as well as more conventional SMT components onto locations on the PCB that have been programmed into the pick-and-place machine. In some embodiments, the components may be prepared on a roll (e.g., a conventional tape roll) for picking and placement (e.g., by the conventional SMT equipment). In one such example, a display tape (which is already sticky) may be or remain on the component, and the component will not move when placed on the substrate (e.g., prior to curing the ACP) in such an example.

In the present method, one or more pick-up nozzles in the pick-and-place/SMT equipment is changed and/or designed to have the same or substantially the same shape as the component it picks up. For example, one or more conventional pick-and-place nozzles in a conventional pick-and-place/SMT machine may be designed to match the size and shape of the respective component. In some cases, the component may have an irregular, non-standard or non-planar surface, in which case the pick-up tool (e.g., nozzle) may need to contact and/or reach a surface below the highest surface on the component. For example, the components are flexible in some embodiments. However, the components may be rigid or stiff in other embodiments.

At 150, the component placement (e.g., the rotation of the component and/or its location on the pads and/or on the substrate) is optionally inspected and/or verified. In one example, the inspection comprises Automated Optical Inspection (AOI), using a machine that includes a camera and that verifies correct rotation of each component and correct placement of the components on the pads of the substrate. Although inspection or AOI is conducted prior to curing the conductive adhesive in the exemplary method 100 of FIG. 1, alternatively or additionally, it can be performed post-curing.

At 160, it is determined whether the rotation and placement of the component on the substrate is correct. This can be done by visual inspection (e.g., using a camera in the pick-and-place/SMT equipment) or by AOI, as described above. At 165, if the component rotation and placement is not correct, the component can be lifted from the substrate and replaced on the substrate. Optionally, additional conductive adhesive (e.g., ACP) may be printed onto the pads on which the component was incorrectly placed. If the component rotation and placement is correct, pressure may be applied to the component. When a sticky display tape is on the component during placement, additional pressure may not be necessary to keep the component from moving after being placed.

After it has been determined that the component rotation and placement is correct, all of the remaining components are placed in their predetermined locations and inspected, then the conductive adhesive (e.g., ACP) is heated at a predetermined temperature for a predetermined length of time at 170 to cure it. In some examples, the conductive adhesive is heated to a temperature of 140° C. or less (e.g., 80-140° C.). Although the length of curing time may be empirically determined for a given component, substrate and conductive adhesive, the curing time may be from 1 second to 5 minutes or more. In some embodiments, pressure is also applied to the component during heating to facilitate curing. The pressure in such embodiments may be greater than 0.1 MPa (e.g., >0.15 MPa), and up to 1 MPa, 10 MPa or more. When curing, the binder(s) in the ACP may causes a predetermined amount of shrinkage, which can force the binder into the two opposing surfaces, thus improving electrical contact and mechanical stability.

The method 100 may further comprise cooling the assembled electronic device, cleaning the substrate and (optionally) the components at 180, then optionally packaging and/or shipping a plurality of such electronic devices. The method 100 then ends at 190.

An Exemplary System for Making an Electronic Device

The present invention also concerns a system for manufacturing an electronic device, comprising screen or stencil printer, the pick-and-place/SMT machine, and a curing oven. In one example, the curing oven comprises a conventional reflow soldering oven.

FIG. 2 shows an exemplary system 200, including a feeder 210, a printer 220, a SMT machine 230, a curing station 240, and a collector 250. The system 200 attaches one or more components having non-standard sizes and/or shapes (as well as standardized components) to a substrate, such as a PCB. Alternatively, the substrate can be flexible (e.g., a plastic, a metal foil, etc.), and may comprise a flexible material secured to a rigid substrate for SMT processing (e.g., for placing and/or mounting the components on such a flexible material). In embodiments in which the adhesive is cured at a temperature of 140° C. or less, the flexible substrate/material can be or comprise polyethylene terephthalate (PET).

The feeder 210 feeds the substrate with electrical traces thereon and connection pads at the ends of the traces into the printer 220. The printer 220 may comprise a screen or stencil printer, and is configured to apply a conductive adhesive (e.g., the ACP) to the substrate on the pad locations. The components may be temporarily adhered to the PCB using the wet conductive adhesive paste itself, or by using small blobs of a separate adhesive, applied by a glue-dispensing machine in the printer 220.

The SMT (surface mount technology) machine 230 is a robotic machine or system that places components onto the substrate in predetermined locations. The components include those having non-standard sizes and/or shapes as described herein, and may also include more conventional surface-mount devices (SMDs). The SMT machine 230 comprises a camera or other inspection equipment 232, a substrate holder or clamp 234, a gantry (including pick-and-place machinery) 236, and a tape-and-reel station 238. In one embodiment, the inspection equipment 232 comprises a camera configured to conduct automated optical inspection (AOI) of the components on the substrate.

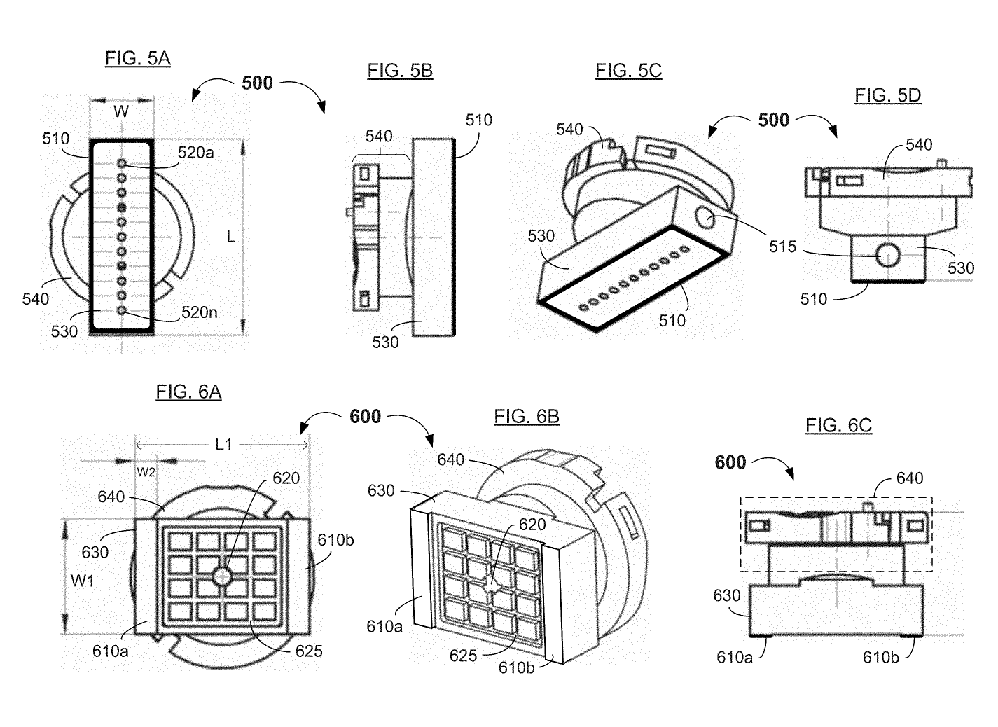

The gantry 236 is a subsystem that picks up, optionally inspects, and places the components on predetermined (e.g., programmed) locations on the substrate. The pick and place machinery in the gantry 236 includes a plurality of nozzles (e.g., a projection-like device with a pneumatic suction cup or similar opening at an end thereof) attached to a plotter-like device that can manipulate the nozzles accurately in three dimensions. Each nozzle may also be rotated independently. At least one of the pick-up nozzles is changed and/or designed to have the same shape as the component it picks up and/or to have a surface that extends below an uppermost surface of the component (see, e.g., FIGS. 5A-6C, discussed below).

In further embodiments, a single gantry 236 may include multiple nozzles with separate and/or independent vertical motion, which enables picking up and placing multiple components on a single trip to the tape-and-reel station 238. For example, one or more nozzles with standard shapes and/or sizes can be used for placing components that are rigid or stiff. Such rigid or stiff components may also have a standard shape and/or size (e.g., for placement using a standard nozzle). Also, the gantry 236 may comprise a plurality of different robotic heads (with corresponding software) to work independently of each other to further increase the throughput of the SMT machine 230.

The tape-and-reel station 238 is located along the front of the SMT machine 230. Alternatively, the tape-and-reel station 238 is located along the back of the SMT machine 230. The components may be supplied on paper or plastic tape, in one or more tape reels that are loaded onto a feeders mounted in or to the SMT machine 230. Alternatively, the components may be arranged in one or more trays which are stacked in a compartment in the tape-and-reel station 238, and are supplied to the substrate in the holder 234 by the pick-and-place machinery in the gantry 236.

In one embodiment, the SMT machine 230 further includes a conveyor belt, along which blank PCBs (i.e., PCBs with electrical traces and pads thereon, but without components thereon) travel, and a PCB clamp (not shown). The conveyor belt passes through the middle of the machine, and the PCB clamp is in the center of the machine. The PCB is clamped in place by the PCB clamp, and the nozzles pick up individual components from the feeders/trays (e.g., in the tape-and-reel section 238), rotate them to the correct orientation, and then place them on the appropriate pads on the PCB with high precision. Some SMT machines 230 can have multiple conveyors to simultaneously produce multiple products (which may be the same or different).

As the component is carried from the tape-and-reel section 238 (or other component feeder) to the PCB in the PCB clamp, it may photographed or imaged (e.g., from below or above). The silhouette of the component is inspected to see if it is damaged or missing (i.e., it was not picked up), and any registration errors in the pickup process are measured and compensated for when the component is placed on the PCB. For example, if the component was shifted 0.25 mm and rotated 10° when picked up, the pickup head can adjust the placement position to place the component in the correct location on the PCB. Some SMT machines have the optical inspection system 232 on a robot arm and can carry out the measurements and calculations without losing time, thereby achieving a lower derating factor. When the optical inspection system 232 is mounted on a head, it can also be used to capture details of the non-standard component and save the details to a memory or database for future use. In addition to this, software is commercially available for monitoring the production and interconnection database (i.e., of the production floor to that of supply chain) in real time. An optional separate camera on the pick-and-place head(s) can photograph fiducial and/or alignment marks on the PCB to measure its position on the conveyor belt accurately. Two fiducial and/or alignment marks, measured in two dimensions each and usually placed diagonally on the PCB, enable the orientation and thermal expansion of the PCB to be measured and compensated for as well. Some SMT machines are also able to measure PCB shear by measuring a third fiducial and/or alignment mark on the PCB.

The curing station 240 may comprise an oven or heater for curing a thermally-curable ACP, and/or a source of UV radiation for curing a photo- or radiation-curable ACP. In the case where the curing station comprises an oven or heater, the oven or heater brings the assembly (i.e., the substrate, conductive adhesive and components) up to a temperature high enough to cure the adhesive (e.g., initiate polymerization of heat-curable monomers in the adhesive using a thermally reactive initiator). For example, the curing temperature may be from 100° C. to 200° C., or any value or range of values therein (e.g., 100° C. to 150° C.), but in one embodiment, the maximum curing temperature can be as low as 140° C.

The collector 250 stores the assembly while the assembly cools, and places the manufactured assemblies into a container or other arrangement for safe and easy handling and/or shipment. When the assembly has cooled to ambient temperature, it is finished and ready to go.

Exemplary Electronic Devices

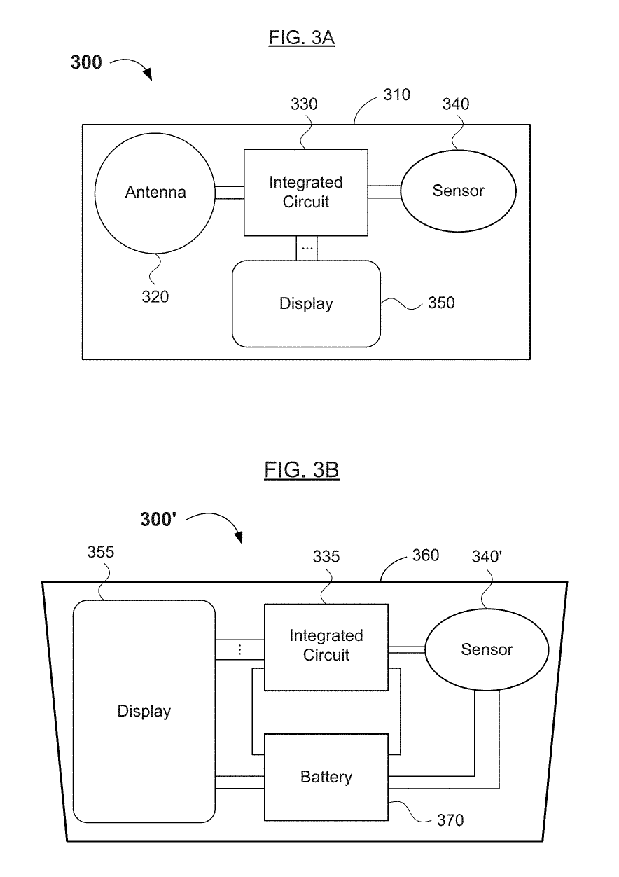

FIGS. 3A-B are block diagrams of exemplary devices 300 and 300′ made using the present method. Referring to FIG. 3A, an antenna 320, an integrated circuit 330, a sensor 340, and a display 350 are placed or mounted on a substrate 310 (e.g., using the method of FIG. 1 described above). The antenna 320, the sensor 340, and the display 350 may have a non-standard size and/or shape.

For example, the antenna 320 shown in FIG. 3A may comprise a spiral or coil, and therefore has a substantially circular peripheral edge. However, substantially straight traces extend from the ends of the spiral or coil to the integrated circuit 330. In such embodiments, an insulator (not shown) must be formed between the loops of the spiral or coil and the trace connecting the inner end of the antenna spiral or coil to the integrated circuit 330. Fabrication of an antenna having an insulation layer in a predetermined location on or over the loops of the spiral or coil may be easier on a substrate separate from the substrate (e.g., PCB) 310. In various embodiments, the antenna substrate may have a non-standard shape as shown in FIG. 3A.

Alternatively, the antenna 320 can be formed directly on the substrate 310 (e.g., at the same time and using the same materials as the metal traces). In one such alternative embodiment, the antenna 320 may be formed as a single-layer spiral or coil (i.e., without the traces extending from the ends of the spiral or coil to the integrated circuit 330), and the integrated circuit 330 (which may be formed by thin-film processing and/or printing on an insulative substrate) may have bonding pads or connections to the antenna 320 through the substrate in locations corresponding to the ends of the spiral or coil. In such an embodiment, the insulative substrate for the integrated circuit 330 may functions as a strap or interposer, crossing over the loops of the antenna spiral or coil and insulating the loops of the antenna spiral or coil from the integrated circuitry 330. Alternatively (i.e., in a face-down arrangement), the integrated circuit 330 may be coated with an insulation or passivation layer, and the bonding pads or connections to the antenna 320 pass through the insulation or passivation layer.

The sensor 340 may also have a non-standard size and/or shape. For example, the sensor 340 may comprise a continuity sensor (see, e.g., U.S. patent application Ser. No. 14/820,378, filed Aug. 6, 2015, the relevant portions of which are incorporated herein by reference), which can be placed on a part of a packaging label that has an irregular shape and/or non-standard size. Alternatively, the sensor 340 may comprise a chemical sensor that provides optimal performance and/or sensitivity when it has a non-standard shape (e.g., circular or oval).

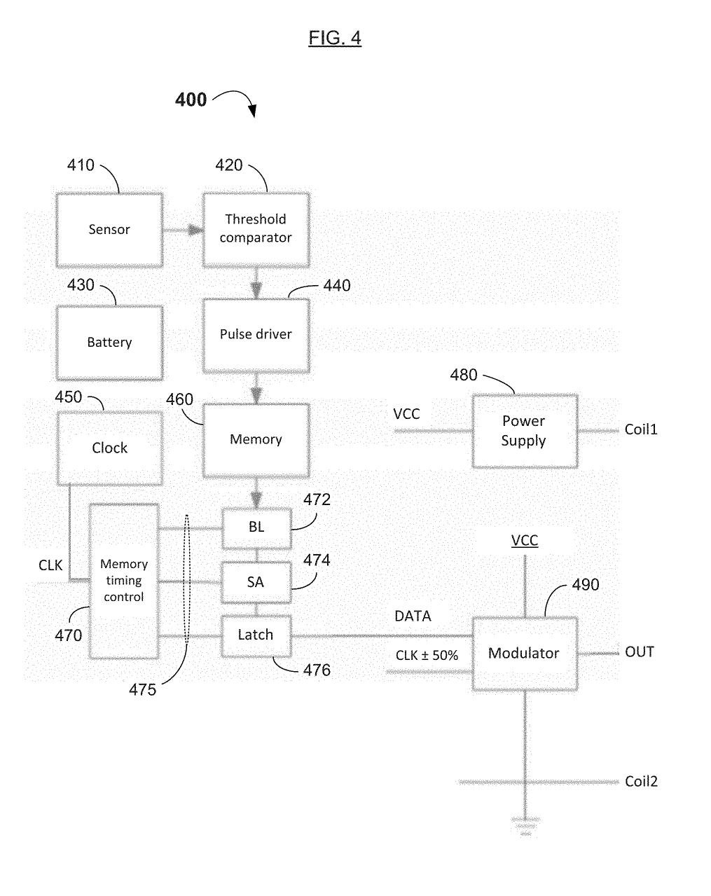

Among other functions, the integrated circuit 330 in FIG. 3A extracts power from the signal received by the antenna 320 and provides the power to other components in the device 300. Thus, the integrated circuit 330 may comprise a rectifier, in addition to other logic (see the discussion of FIG. 4 below). The display 350 may be or comprise a single- or multi-color electrochromic or LED (e.g., organic LED) display receiving one or more single- or multi-bit data and/or control signals from the integrated circuit 330. In some embodiments, the display 350 may be printed on a flexible substrate prior to mounting onto the substrate 310.

The sensor 340 provides a sensing function, and may determine (a) the presence or absence of one or more chemicals in the environment in which the device 300 is placed, (b) a continuity and/or security state of a package to which the device 300 is attached, (c) a temperature of the environment in which the device 300 is placed, (d) a freshness state of goods in a container to which the device 300 is attached, etc. Thus, the sensor 340 may comprise one or more chemical sensors, continuity sensors, temperature sensors, humidity sensors, timers, etc., and the integrated circuit 330 may comprise one or more comparators, each receiving one input from a corresponding sensor 340 and another input corresponding to a threshold value for comparison with the input from the sensor 340. The threshold value(s) may be stored in a memory in the integrated circuit 330.

The exemplary device 300′ of FIG. 3B includes a battery 370 and a quadrilateral substrate 360, a sensor 340′ and a display 355 with non-standard shapes. The substrate 360 can be flexible (e.g., a plastic, a metal foil, paper, a laminate or other combination thereof, etc.). However, if the substrate 360 cannot be flexible (e.g., the SMT machine can process only rigid substrates), the substrate 360 may comprise a flexible material secured to a rigid substrate for SMT processing, and the components can be placed and/or mounted of the flexible material.

In the device 300′, the battery 370 supplies power to the integrated circuit 335, the sensor 340′ and the display 355, so the battery 370 may be centrally located on the substrate 360 (e.g., so that none of the traces from the battery 370 to other components on the substrate 360 cross over another trace). The integrated circuit 335 is substantially the same as or similar to the integrated circuit 330 in FIG. 3A, except that the integrated circuit 335 does not provide power to other components in the device 300′. The sensor 340′ is substantially the same as or similar to the sensor 340 in FIG. 3A, except that the sensor 340′ receives power from the battery 370. The display 355 is substantially the same as or similar to the display 350 in FIG. 3A, except that the display 355 receives power from the battery 370 and may have different dimensions.

FIG. 4 is a block diagram of an exemplary integrated circuit (IC) 400, suitable for use as the integrated circuit 330 in FIG. 3A. It is well within the level of skill of one skilled in the art to modify the integrated circuit 400 for use as the integrated circuit 335 in FIG. 3B. Optional components in the exemplary integrated circuit 400 can be omitted from the integrated circuits 330 and 335 in FIGS. 3A-B.

As shown in FIG. 4, the IC 400 may include one or more sensors 410, an optional threshold comparator 420 receiving information (e.g., a signal) from the sensor 410, an optional pulse driver 440 receiving an output of the threshold comparator 430, a memory 460 storing (i) sensor data from the pulse driver 440 and/or (ii) identification code, one or more bit lines (BL) 472 for reading data from the memory 460, one or more sense amplifiers (SA) 474 for converting signals on the bit line(s) 472 to digital signals, one or more optional latches 476 for temporarily storing data from the sense amplifier(s) 474, and a transmitter (e.g., modulator) 490 configured to output data (including identification code) from the device. The exemplary IC 400 in FIG. 4 also contains a clock 450 configured to provide a timing signal (e.g., CLK) that controls the timing of certain operations in the IC 400 and a memory timing control block or circuit 470 that controls the timing of memory read operations. The modulator 490 also receives the timing signal (CLK) from the clock circuit 450, or a slowed-down or sped-up variation thereof. The exemplary IC 400 also includes a power supply block or circuit 480 that provides a direct current signal (e.g., VCC) to various circuits and/or circuit blocks in the IC 400. The portion of the memory 460 containing identification code may be printed, as may other layers and/or blocks of circuitry in the IC 400 (e.g., the power supply 480, which may be or comprise a full-bridge or half-bridge rectifier). The IC 400 may further contain a receiver (e.g., a demodulator), one or more optional rectifiers (e.g., a rectifying diode, one or more half-bridge or full-bridge rectifiers, etc.), one or more optional tuning or storage capacitors, etc. Terminals in the modulator 490 and the power supply 480 (which may comprise a half-bridge or full-bridge rectifier) are connected to ends of the antenna (e.g., at Coil1 and Coil2). The memory 460 and threshold comparator 420 are particularly useful for embodiments that include the sensor 410.

The memory 460 may contain a fixed number of bits. In some implementations (e.g., when the IC 400 is part of an NFC and/or RFID tag), the memory 460 may contain m*2ⁿ bits, where m is a positive integer and n is an integer of at least 3 (e.g., 24, 32, 48, 64, 128, 256 or more bits). Some bits are allocated to overhead (non-payload) data for format identification and data integrity (CRC) checking. The payload of the device (e.g., electronic device 300 or 300′ in FIGS. 3A-B) consumes the remainder of the bits. For example, the payload can be up to (m−p)*2ⁿ bits, where p is a positive integer <m (e.g., 96 bits in the case where m*2ⁿ=128 bits and up to 224 bits in the case where m*2ⁿ=256 bits).

The payload of an NFC and/or RFID tag can be allocated to variable amounts of fixed ROM bits (which are generally—but not always—used as a unique identification number). When print methods are used in manufacturing NFC and/or RFID tags, flexible and/or non-standard substrates can be used, but the ROM bits are permanently encoded and cannot be electrically modified. Any payload bits that are not allocated as fixed ROM bits can be allocated as dynamic sensor bits. These sensor bits can change values, based on a sensed input. Different splits or allocations between ROM and sensor bits are indicated by data format bits that are part of the non-payload or “overhead” bits, generally in the first 2ⁿ bits (or 2^{n-q} bits, where q is a positive integer <n, such as 16 bits in the case where m*2ⁿ=128 or 256) of the NFC and/or RFID tag memory.

Exemplary SMT Nozzles

FIGS. 5A-D show various views of an SMT nozzle 500 suitable for use in the present method. FIG. 5A is a bottom view of the nozzle 500. The head portion 530 of the nozzle 500 that contacts the component has a length L, a width W and a shape matching or substantially matching the shape of the component to be placed on the SMT substrate. The surface of the nozzle head 530 has a raised bead, edge or rim 510 around the periphery that ensures contact with the peripheral surface of the component, even if the component is flexible and/or has a non-planar surface topography. The nozzle 500 may be adapted for placement of a component having a rectangular shape with rounded corners, such as the displays 350 and 355 in FIGS. 3A-B. The nozzle head 530 also includes a series of holes or openings 520a-520n configured to hold the component onto the nozzle 500 upon application of a vacuum through the holes or openings 520a-520n.

FIG. 5B shows a side view of the SMT nozzle 500, including the head 530, the raised bead 510 thereon, and a conventional connector or locking portion 540. The connector 540 connects the nozzle 500 to a wand or similar placement device in the pick-and-place machinery (e.g., in the gantry 236 in SMT machine 230 in FIG. 2). FIG. 5C shows a perspective view of the SMT nozzle 500, including the head 530, the raised bead 510 thereon, and the connector 540. The nozzle head 530 further includes an opening 515 in an end or side surface thereof for attachment of a connector to a vacuum source, such as a pump (not shown). The opening 515 is in gaseous communication with the holes or openings 520a-520n. FIG. 5D shows an end view of the SMT nozzle 500, including the head 530, the raised bead 510 thereon, the opening 515 therein, and the connector 540.

FIGS. 6A-C show various views of another SMT nozzle 600 suitable for use in the present method. FIG. 6A is a bottom view of the nozzle 600. The nozzle head 630 that contacts the component has a length L1, a width W1 and a shape matching or substantially matching the shape of the component to be placed on the SMT substrate. The nozzle head 630 has a plurality of raised surfaces or edges 610a-b on peripheral surfaces of the nozzle head 630 that ensure contact with peripheral surfaces of the component, even if the component is flexible and/or has a non-planar surface topography. Each of the raised surfaces 610a-b in FIGS. 6A-C has a width W2 and a length equal to the width W1 of the nozzle head 630, although other dimensions may be suitable for other embodiments or variations. The nozzle 600 may be adapted for placement of a component having a square or rectangular shape with raised and/or uneven topography in a central region thereof and bonding connectors (e.g., conductive bumps, pads, solder balls, etc.) on opposed end regions thereof, such as the integrated circuit 335 and the battery 370 in FIG. 3B. The nozzle head 630 also includes a hole or opening 620 and an array and/or grid of slots and/or grooves 625 configured to hold the component onto the nozzle 600 upon application of a vacuum through the hole or opening 620.

FIG. 6B shows a perspective view of the SMT nozzle 600, including the head 630, the raised surfaces 610a-b thereon, the opening 620, the array and/or grid of slots and/or grooves 625, and a conventional connector or locking portion 640. The connector 640 connects the nozzle 600 to a wand or similar placement device in the pick-and-place machinery (e.g., in the gantry 236 in SMT machine 230 in FIG. 2). FIG. 6C shows an end view of the SMT nozzle 600, including the head 630, the raised surfaces 610a-b thereon, and the connector 640. The nozzle 600 may further include a vacuum connector/opening (not shown) in gaseous communication with the hole or opening 620 for attachment of a connector to a vacuum source, such as a pump. The vacuum connector/opening may be in an end or side surface of the nozzle 600 or in/through the connector 640.

### CONCLUSION

The present invention advantageously avoids the high cost of full-system assembly (pick and place) associated with high-end SMT machines. The present method can be implemented using basic and/or standard, low-cost machines widely available using standard SMT services and/or processing. The present invention also avoids the relatively high temperatures associated with solder and solder reflux processes, and addresses shortcomings of nozzles with standard shapes and SMT equipment that is incompatible with flexible components.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

1. A method of manufacturing an electronic device, comprising:
a) printing a conductive adhesive onto pads at ends of traces on a substrate;
b) placing one or more components having a non-standard size and/or shape onto the pads with the conductive adhesive thereon; and
c) after the component(s) have been placed onto the pads of the substrate, curing the conductive adhesive at a predetermined temperature or with light having a predetermined wavelength or wavelength band.

2. The method of claim 1, wherein the conductive adhesive is cured at the predetermined temperature, and the predetermined temperature is in the range of from 50° C. to 140° C.

3. The method of claim 1, wherein the conductive adhesive is an anisotropic conductive paste (ACP), comprising:
a) one or more polymerizable monomers;
b) one or more co-monomers that is co-polymerized with the polymerizable monomers, the one or more co-monomers having a formula with at least three functional groups that are co-polymerizable with the one or more polymerizable monomers; and
c) one or more conductive filaments or particles dispersed in the ACP.

4. The method of claim 3, wherein the ACP further comprises a thermally activated initiator.

5. The method of claim 1, wherein said substrate is flexible and comprises a plastic sheet or film, paper, a metal foil or film, or a combination thereof.

6. (canceled)

7. The method of claim 1, wherein said one or more components are placed onto the pads using a standard and/or uncustomized surface mount technology (SMT) machine.

8. (canceled)

9. A system for manufacturing an electronic device, comprising:
a) a printer configured to print a conductive adhesive onto pads at ends of traces on a substrate;
b) a surface mounting machine, configured to place one or more components having a non-standard size and/or shape onto the pads with the conductive adhesive thereon; and
c) a curing station, configured to cure the conductive adhesive after the component(s) have been placed onto the pads of the substrate.

10. The system of claim 9, further comprising a feeder configured to feed said substrate into said printer, and a collector configured to receive said substrate from said curing station.

11. The system of claim 9, wherein said surface mounting machine comprises a substrate holder or clamp, a gantry, and a tape-and-reel station.

12. The system of claim 9, wherein said surface mounting machine further comprises a camera or other inspection equipment.

13. The system of claim 9, wherein said printer comprises a screen or stencil printer.

14. An electronic device, comprising:
a) a substrate having a plurality of traces thereon, each of said traces having a pad at one or more ends thereof;
b) one or more components having a non-standard size and/or shape, wherein each of the one or more components is on a first subset of the pads; and
c) a cured conductive adhesive between the pads and the one or more components, the cured conductive adhesive electrically connecting one of the pads to a corresponding terminal of the one or more components.

15. The device of claim 14, further comprising one or more additional components having a standard size and/or shape on a second subset of the pads.

16. The device of claim 15, wherein said one or more components are selected from the group consisting of a sensor, an antenna, and a display, and said one or more additional components are selected from the group consisting of an integrated circuit and a battery.

17. The device of claim 16, wherein one or more layers of said sensor, said antenna, said display, said integrated circuit and/or said battery comprise a printed material.

18. The device of claim 14, wherein said substrate is flexible and comprises a plastic sheet or film, paper, a metal foil or film, or a combination thereof.

19. (canceled)

20. The device of claim 14, wherein the conductive adhesive is an anisotropic conductive paste (ACP), comprising:
a) one or more polymerizable monomers;
b) one or more co-monomers that is co-polymerized with the polymerizable monomers, the one or more co-monomers having a formula with at least three functional groups that are co-polymerizable with the one or more polymerizable monomers; and
c) one or more conductive filaments or particles dispersed in the ACP.

21. A curable conductive adhesive, comprising:
a) an initiator that is thermally activated or activated upon irradiation with light having a wavelength within a predetermined band;
b) one or more monomers that are polymerized by the activated initiator;
c) one or more co-monomers that are co-polymerized with the monomers, the one or more co-monomers having a formula with at least three functional groups that are co-polymerizable with the one or more monomers by the activated initiator; and
d) elastic conductive filaments or particles dispersed in the conductive adhesive, wherein the conductive adhesive is curable at a temperature of 150° C. or less.

22. (canceled)

23. The conductive adhesive of claim 21, wherein said elastic conductive filaments or particles comprise elastic particles coated with an elemental, conductive metal or alloy.

24. (canceled)

25. The conductive adhesive of claim 21, wherein said one or more co-monomers are selected from the group consisting of C₁-C₄ esters of C₇-C₁₂ triacrylates and C₁₀-C₁₂ trimethacrylates.
